(19) United States
(12) Patent Application Publication
(10) Pub. No.: US 2006/0103402 A1
(43) Pub. Date: May 18, 2006

(54) Semiconductor apparatus

(75) Inventor: Hideaki Kondou, Kyoto-shi (JP)

Correspondence Address: PANASONIC PATENT CENTER;c/o MCDERMOTT WILL & EMERY LLP, 600 13TH STREET, NW, WASHINGTON, DC, 20005-3096, US

(73) Assignee: MATSUSHITA ELECTRIC INDUSTRIAL CO., LTD.

(21) Appl. No.: 11/270,605

(22) Filed: Nov. 10, 2005

(30) Foreign Application Priority Data
Nov. 12, 2004 (JP) 2004-329114

(51) Int. Cl. G01R 31/02

(52) U.S. Cl. 324/754

(57) ABSTRACT

A semiconductor apparatus according to the present invention comprises a semiconductor wafer, a plurality of semiconductor chips provided on the semiconductor wafer, a dicing lane provided between the adjacent two semiconductor chips and representing a region to be cut off when the semiconductor wafer is cut for each of the semiconductor chips and a plurality of probing pads disposed in a row on the dicing lane, and connecting parts for connecting the respective probing pads to one of the semiconductor chips facing each other with the probing pads interposed therebetween, wherein the semiconductor chips are connected to at least one of the plurality of probing pads via the connecting parts.

### BACKGROUND OF THE INVENTION

1. Field of the Invention

The present invention relates to a semiconductor apparatus for which a high security is demanded such as an IC card, more particularly to a technology of disabling any access/analysis via a probing pad and thereby improving a tamper-resistance performance serving as a function of providing a physical protection for a chip by disposing the probing pad in a chip-dicing region and cutting it off in a dicing process.

2. Description of the Related Art

An IC card stores therein important data such as personal information and monetary information. Therefore, a tamper-resistance technology for preventing the modification and falsification of the important data without any approval is vital. The tamper-resistance technology ranges in a wide variety, one of which is a technology of cutting off a probing pad disposed on a dicing lane along the dicing lane in a dicing process in which a chip is separated from a wafer.

FIG. 7 is an illustration of a physical chip configuration in a semiconductor apparatus according to a conventional technology. In semiconductor chips (hereinafter, simply referred to as chips) A1 and A2 provided on a wafer W, connecting parts 3 extend from a plurality of places spaced at predetermined intervals toward an outer side in an X direction on right sides of internal circuits 1. Top-end portions of the connecting parts 3 are disposed on linear dicing lanes 4, and the connecting parts 3 are connected to probing pads 2 on the dicing lanes 4. The chip A1 and the Chip A2 adjacent thereto are thus configured. The dicing lanes 4 are respectively exclusive to the different chips A1 and A2. The foregoing array pattern is repeatedly employed in the plurality of chips in the X direction.

A test of the internal circuits 1 in the respective chips is performed in the foregoing state of the wafer W via the probing pads 2. When the test is completed, the probing pads 2 are no longer necessary. Therefore, the probing pads 2 are cut off along the dicing lanes 4 in a dicing process thereafter implemented so that the chips A1 and A2 are separated. The chips A1 and A2 are installed in the IC card or the like.

When a third person tries to retrieve the LSI chip from the IC card or the like to thereby analyze it, the absence of the probing pads 2 resulting from the cutting-off operation makes it impossible to read signals of the internal circuits 1 so that an illegal analysis can be prevented.

Such a technology is recited in No. H10-256324 (hereinafter, referred to as Patent Literature 1), No. 2001-135597 (hereinafter, referred to as Patent Literature 2), No. 2003-77968 (hereinafter, referred to as Patent Literature 3) and No. 2003-203913 (hereinafter, referred to as Patent Literature 4) of the Publication of the Unexamined Japanese Patent Applications.

In the Patent Literature 1, the pads are provided on the right-side row alone. Referring to a wiring layout, therefore, it is necessary to provide the wiring from the chip (internal circuit) toward the right side. However, such a restriction in the wiring layout deteriorates an efficiency in the layout. For example, when the wiring is necessarily provided from the left side toward the right side of the chip, a length of the wiring is extended resulting in delays in the wiring. This leads a margin of an operation timing to be lowered, and further, leads a cost for manufacturing the chip to be increased.

In the Patent Literature 4, the pads are arranged in a row in the dicing regions in the two chips adjacent to each other, and the two rows of pads are cut off in the dicing process, in which case the dicing regions are extended, thereby increasing the area to be cut off. As a result, an effective region on the wafer is reduced, resulting in the increased chip cost, and further, probing needles in a probing test or a wafer level burn-in test unfavorably focus on the dicing regions. Input/output circuits are convergently provided on the sides on which the probing needles focus. Further, it is necessary to physically provide a certain degree of interval between the probing needles, which makes it difficult to manufacture the probing needles. As a further disadvantage, a restriction imposed on pitches of the probing needles may demand a plurality of tests on one wafer, which increases a testing cost.

The Patent Literature 4 also has a disadvantage in terms of security, that is, a cut sectional surface easily invites the analysis if the probing pads are simply cut off. In other words, it is impossible to completely block any access into the chip via the probing pads.

### SUMMARY OF THE INVENTION

Therefore, a main object of the present invention is to avoid the convergence of a pad wiring on any particular side and thereby improve a layout efficiency and a design quality.

In order to solve the aforementioned problems, a semiconductor apparatus according to the present invention comprises a semiconductor wafer, a plurality of semiconductor chips provided on the semiconductor wafer, a dicing lane provided between the adjacent two semiconductor chips and representing a region to be cut off when the semiconductor wafer is cut for each of the semiconductor chips, a plurality of probing pads disposed in a row on the dicing lane, and connecting parts for connecting the respective probing pads to one of the semiconductor chips facing each other with the probing pads interposed therebetween. The both semiconductor chips are connected to at least one of the plurality of probing pads via the connecting parts.

According to the foregoing constitution, a scribe region (dicing lane) can be shared by the adjacent chips, which prevents the scribe region from increasing and also prevents the chip cost from increasing. Further, pitches of the probing pads in the respective chips can be alleviated, a testing cost can be prevented from increasing, and a tamper-resistance performance can be improved.

According to a preferred mode of the present invention, the semiconductor chips connected to the probing pads by the connecting parts are replaced on a regular basis along the dicing lane, or the semiconductor chips connected to the probing pads by the connecting parts are replaced on an irregular basis along the dicing lane. The irregular replacement can make the analysis even more difficult.

According to a more preferred mode of the present invention, the probing pads are disposed in a row based at identical pitches in a pair of dicing lanes facing each other with one of the semiconductor chips interposed therebetween, and one of the two probing pads at identical positions in the respective rows of the pair of dicing lanes is connected to the one of the semiconductor chips by the connecting parts.

According to the foregoing constitution, the probing pads are separately disposed in each of the pair of dicing lanes facing each other with one of the semiconductor chips interposed therebetween so that the probing pads are less focused on any particular dicing lane. As a result, the layout efficiency and the design quality can be prevented from deteriorating. Further, the pads disposed on the dicing lanes receive a signal, not through the wiring on one of the probing pads, but through the respective wirings of the pair of dicing lanes facing each other, which increases the difficulty in the analysis and thereby improves the tamper-resistance performance. Therefore, if an illegal action such as the physical analysis via cut sectional surfaces generated in the dicing process and restoration of the pads, the restoration is made more difficult.

According to another more preferred mode of the present invention, the probing pads are disposed in a row at identical pitches in another pair of dicing lanes facing each other with one of the semiconductor chips interposed therebetween, and one of the two probing pads at identical positions in the respective rows of the another pair of dicing lanes is connected to the one of the semiconductor chips by the connecting parts.

According to the foregoing constitution, the probing pads can be disposed in an entire circumference of the semiconductor chip if the semiconductor chips have, for example, a rectangular shape, which further reduces the convergence of the probing pads on any particular side. As a result, the layout efficiency and the design quality can be further improved. As a further advantage, the tamper-resistance performance can be further improved.

According to still another more preferred mode of the present invention, a stepper alignment mark is disposed in the respective dicing lanes. More specifically, the entire region of the dicing lanes includes a region where components such as accessories can be disposed instead of using the entire region for disposing the probing pads.

According to the foregoing constitution, a degree of freedom in the layout of the dicing lanes in a reticle design can be enhanced.

According to still another more preferred mode of the present invention, dummy connecting parts for connecting the respective probing pads to the other semiconductor chip unconnected via the connecting parts are further provided.

According to the foregoing constitution, the dicing sectional-surfaces is provided with a trace of the cut-off operation of the dummy connecting parts not connected to the semiconductor chips as if it is drawn into the chip apart from a trace of the cut-off operation of the probing pads. Therefore, the tamper-resistance performance against the illegal analysis can be further improved.

According to still another more preferred mode of the present invention, a short-circuit connecting part for short-circuiting the connecting parts by means of a damage generated in the dicing process is provided between the connecting parts connected to the same semiconductor chip and adjacent to each other.

According to the foregoing constitution, it is necessary to cancel the short-circuited state of the connecting parts generated by the short-circuit connecting part and separate the connecting parts when the analysis is performed via the dicing sectional surface. Thereby, the illegal analysis becomes even more difficult, and the tamper-resistance performance can be further improved.

To describe a specific example of the constitution of the short-circuit connecting part, the short-circuit connecting part comprises a pair of comb-like conductors disposed along an edge of the dicing lane, wherein one of the comb-like conductors is connected to one of the connecting parts adjacent thereto, the other of the comb-like conductors is connected to the other of the connecting parts adjacent thereto, and top-ends of the both comb-like conductors are drawn into each other in a comb-teeth manner in an non-connected state.

According to the present invention constituted as above, the scribe region is shared by the adjacent chips, which prevents the scribe region from increasing and thereby prevents the chip cost from increasing. Further, the pitches of the probing pads in the respective chips can be alleviated, the increase of the testing cost can be prevented, and the security can be improved.

The present invention is effective for providing a high tamper-resistance performance for a chip demanding the improvement of the tamper-resistance performance for preventing the modification and falsification of important data, such as personal information and monetary information stored in an IC card or the like, without any approval, without being subjected to any restriction in the layout design and positions of the probing pads in the wafer test.

### BRIEF DESCRIPTION OF THE DRAWINGS

These and other objects as well as advantages of the invention will become clear by the following description of preferred embodiments of the invention, and a number of benefits not recited in this specification will come to the attention of the skilled in the art upon the implementation of the present invention.

FIG. 1 shows a physical chip configuration according to an embodiment 1 of the present invention.

FIG. 2 shows a physical chip configuration according to an embodiment 2 of the present invention.

FIG. 3 shows a physical chip configuration according to an embodiment 3 of the present invention.

FIG. 4 shows a physical chip configuration according to an embodiment 4 of the present invention.

FIG. 5 shows a physical chip configuration according to an embodiment 5 of the present invention.

FIG. 6 shows a physical chip configuration according to an embodiment 6 of the present invention.

FIG. 7 shows a physical chip configuration according to a conventional technology.

### DETAILED DESCRIPTION OF THE INVENTION

Hereinafter, preferred embodiments of a semiconductor apparatus according to the present invention are described in detail referring to the drawings.

### Embodiment 1

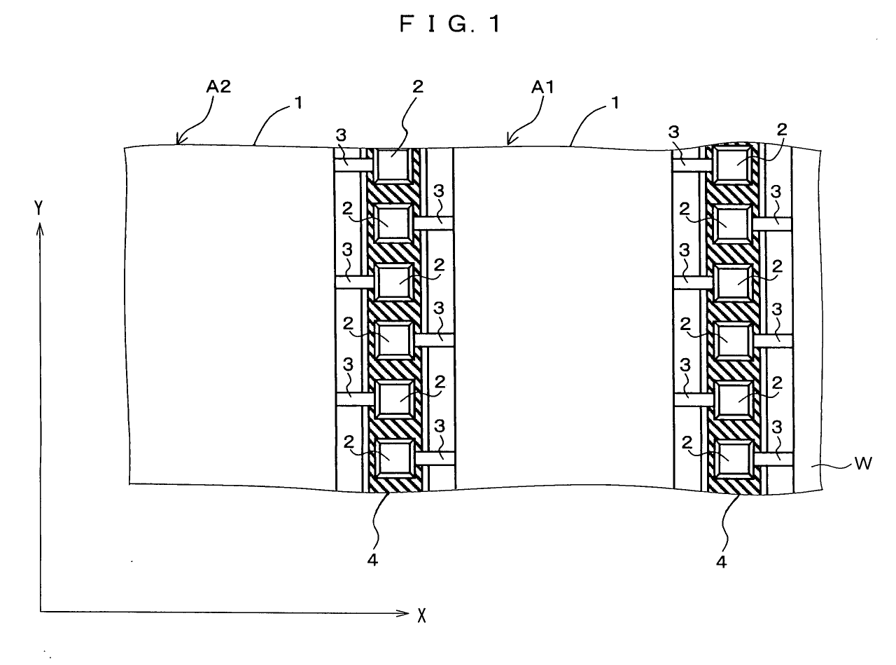

FIG. 1 shows a physical chip configuration in a semiconductor apparatus according to an embodiment 1 of the present invention. Semiconductor chips (hereinafter, simply referred to chips) are disposed in an X direction on a semiconductor wafer (hereinafter, simply referred to as wafer). More specifically, chips A1-An (n is an optional integer) are disposed in an aligned manner in X and Y directions. Below are described constitutions of the adjacent chips A1 and A2 as examples of the chips A1-An. Referring to reference symbols and numerals in FIG. 1, W denotes a wafer, A1 and A2 denote rectangular chips adjacent to each other, 1 denotes internal circuits formed in the semiconductor chips A1 and A2, 2 denotes probing pads, 3 denotes connecting parts, and 4 denotes dicing lanes. The internal circuit 1, for example, realizes a desired function in LSI in an IC card. For the convenience of the description, a horizontal direction is referred to as the X direction, while a vertical direction is referred to as the Y direction.

Between the chips A1 and A2 are provided the dicing lanes 4 representing regions to be cut off when the wafer W is cut in the respective semiconductor chips A1 and A2. In FIG. 1, the dicing lanes 4 along the Y direction are shown. The chips A1 and A2 share the dicing lanes 4.

The probing pads 2 on the left side of the chip A1 and the probing pads 2 on the right side of the chip A2 are arranged in a row at identical pitches (with an equal interval interposed therebetween) on the dicing lanes 4.

The chips A1 and A1 respectively comprise a plurality of connecting parts 3. The connecting parts 3 are disposed on the respective left and right sides (sides on two sides of the X direction) of the chips A1 and A2 and extend outward in the X direction (outward in the horizontal direction in the drawing) from main-body parts of the chips A1 and A2. The connecting parts 3 are disposed in parallel at identical pitches with a predetermined interval provided therebetween, however, the connecting parts 3 disposed on the right side of the chip and the connecting parts 3 disposed on the left side of the chip are not disposed at the same positions in the Y direction but alternately disposed. More specifically, when the positions at which the respective connecting parts 3 are disposed in the Y direction are compared to one another, the connecting parts 3 disposed on the right side are disposed between the connecting parts 3 disposed on the left side and adjacent to one another.

The probing pads 2 are connected to top ends of all of the connecting parts 3. The probing pads 2 connected to the connecting parts 3 on the left side of the chip A1 and the probing pads 2 connected to the connecting parts 3 on the right side of the chip A2 are disposed in a row along the Y direction in such manner that they are each alternately disposed per pad. The respective probing pads 2 are connected to one of the chips A1 and A2 facing each other with the probing pads 2 interposed therebetween via the connecting parts 3. Further, the chips A1 and A2 are respectively connected at least one of the plurality of probing pads 2 via the connecting parts 3. In the present embodiment, the chips A1 and A2 alternately connected to the probing pads 2 along the direction where the probing pads 2 are arranged are subjected to exchange. The chips A1 and A2 connected to the probing pads 2 by the connecting parts 3 are regularly exchanged along the direction of the dicing lanes 4.

The array pattern as described above is repeatedly employed in the plurality of chips in the X direction.

A test of the internal circuits 1 in the respective chips A1 and A2 is carried out when a probing test is performed on the wafer W via the probing pads 2. To be specific, the internal circuits 1 are made to execute a desired operation in a state where probes of a tester are in contact with the probing pads 2, and signals of the internal circuits 1 are observed with the tester via the connecting parts 3 and the probing pads 2 and compared to a test pattern previously prepared.

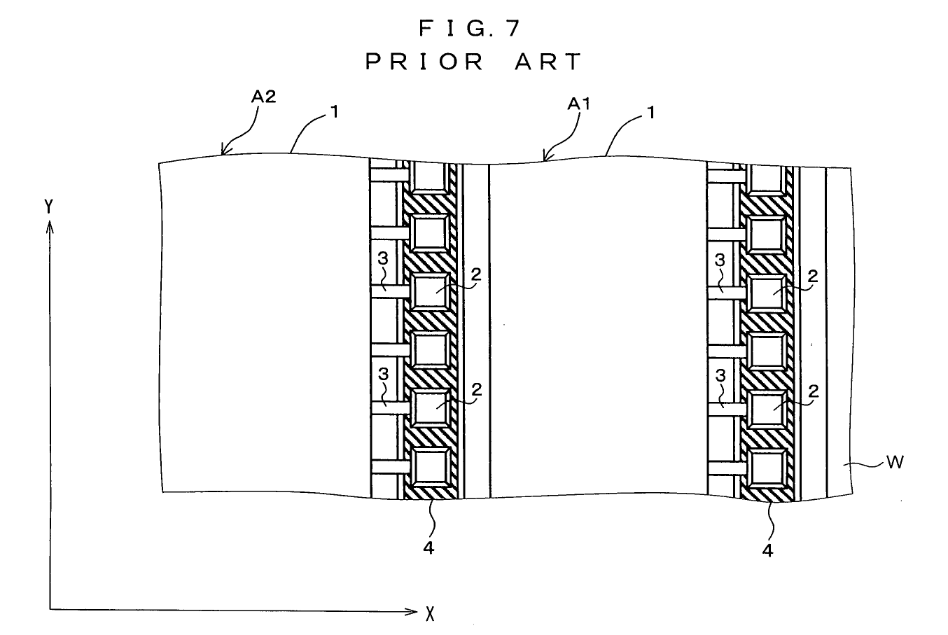

After the completion of the probing test, the probing pads 2 are removed along the dicing lanes 4 in a dicing process so that the chip A1 is separated. At the time, the wafer dicing process in the same manner as in the conventional technology shown in FIG. 7 can be performed because the probing pads 2 are arranged in a row.

The separated chip A1 is installed in the IC card or the like. When a third person tries to peal the desired chip off the IC card or the like and analyze it in his/her pursuit of an illegal success with respect to the internal circuit 1 of the chip, the probing pads 2 have already been cut off and removed. Therefore, it is difficult to observe the signal of the internal circuit 1 from the probing pads 2 in the same manner as in the test performed on the wafer W, which makes it impossible to analyze the internal circuit 1.

Further, the probing pads 2 connected to the chips A1 and A2 are not convergently disposed on one side as in the conventional technology shown in FIG. 7 but separately disposed on the left and right sides. Therefore, the convergence of input/output circuits are one side can be prevented, which improves the layout efficiency in the wiring.

The probing pads 2 are each alternately disposed in a row per pad on the chip-A1 side and the chip-A2 side adjacent thereto. Therefore, the pitches of the probing pads 2 are doubled in comparison to the conventional technology shown in FIG. 7 in each semiconductor apparatus. As a result, pitches of needles used in the probing test can be enlarged, which facilitates the test.

### Embodiment 2

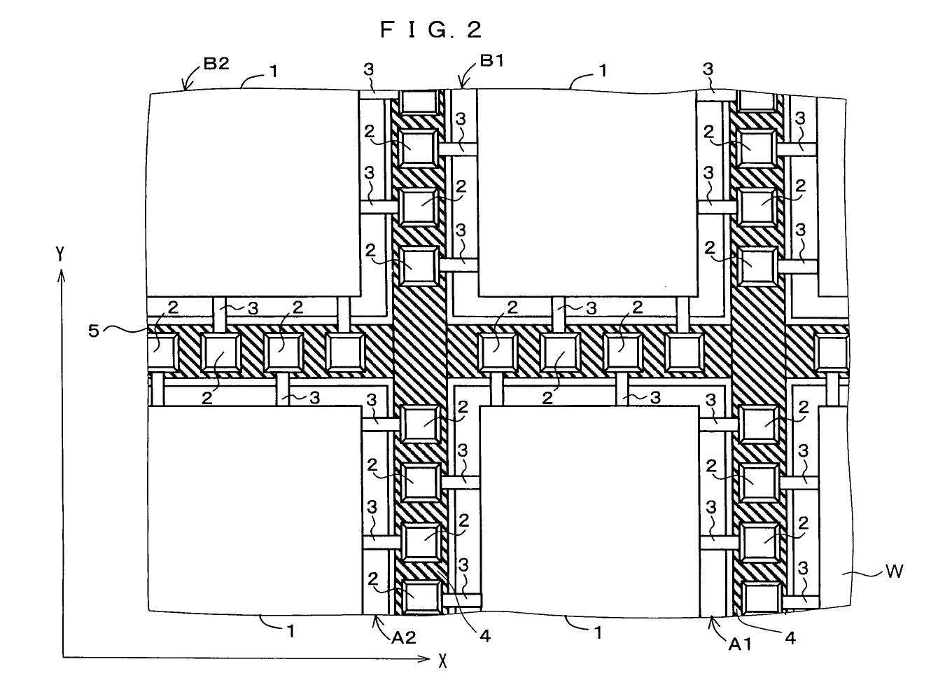

FIG. 2 shows a physical chip configuration in a semiconductor apparatus according to an embodiment 2 of the present invention. Chips having a rectangular shape in plan view are disposed in the aligned manner on the wafer W in the X and Y directions. However, the chips according to the present embodiment are not necessarily rectangular, and the present invention can be implemented as long as the chips have a shape having opposing sides.

Below are described constitutions of chips A1, A2, B1 and B2 adjacent to one another as examples of a plurality of chips. The chips A1 and A2 are adjacent to each other in the X direction, the chips B1 and B2 are adjacent to each other in the X direction, the chips A1 and B1 are adjacent to each other in the Y direction, and the chips A2 and B2 are adjacent to each other in the Y direction. A reference numeral 4 denotes dicing lanes provided between the adjacent chips and along the Y direction. A reference numeral 5 denotes dicing lanes provided between the adjacent chips and along the X direction. The rest of the constitution is the same as described in the embodiment 1.

The chips A1, A2, B1 and B2 respectively comprise a plurality of connecting parts 3. The connecting parts 3 are respectively disposed on sides of an entire circumference of each of the chips A1, A2, B1 and B2 (sides on two sides in the X direction and sides on two sides in the Y direction), and extend outward in the X direction (outward in the horizontal direction in the drawing) and outward in the Y direction (outward in the vertical direction in the drawing) from main-body parts of the chips A1, A2, B1 and B2. The connecting parts 3 are disposed in parallel at identical pitches (with a predetermined interval provided therebetween). However, the connecting parts 3 disposed on the right side of the chip and the connecting parts 3 disposed on the left side of the chip are not disposed at the identical positions in the Y direction but alternately disposed. To be specific, when the positions at which the connecting parts 3 are disposed in the Y direction are compared to one another, the connecting parts 3 disposed on the right side are disposed between the connecting parts 3 disposed on the left side and adjacent to each other.

In the same manner, the connecting parts 3 disposed on the upper side of the chip and the connecting parts 3 disposed on the lower side of the chip are not disposed at the identical positions in the X direction but alternately disposed. To be specific, when the positions at which the connecting parts 3 are disposed in the X direction are compared to one another, the connecting parts 3 disposed on the upper side are disposed between the connecting parts 3 disposed on the lower side and adjacent to each other.

The probing pads 2 are connected to top ends of all of the connecting parts 3. The probing pads 2 connected to the connecting parts 3 on the left sides of the chips A1 and B1 and the probing pads 2 connected to the connecting parts 3 on the right sides of the chips A2 and B2 are disposed in a row along the Y direction in such manner that they are each alternately disposed per pad.

In the same manner, the probing pads 2 connected to the connecting parts 3 on the upper sides of the chips A1 and A2 and the probing pads 2 connected to the connecting parts 3 on the lower sides of the chips B1 and B2 are disposed in a row along the Y direction in such manner that they are each alternately disposed per pad.

Between the chips A1 and B1 and the chips A2 and B2 are disposed the dicing lanes 4 along the Y direction. The chips A1, A2, B1 and B2 share the dicing lanes 4. The probing pads 2 on the left sides of the chips A1 and B1 and the probing pads 2 on the right sides of the chips A2 and B2 are disposed on the dicing lanes 4 in a row in such manner that they are equally spaced (provided at identical pitches).

Between the chips A1 and A2 and the chips B1 and B2 are provided dicing lanes 5 along the X direction. The chips A1, A2, B1 and B2 share the dicing lanes 5. The probing pads 2 on the upper sides of the chips A1 and A2 and the probing pads 2 on the lower sides of the chips B1 and B2 are disposed on the dicing lanes 5 in a row in such manner that they are equally spaced (provided at identical pitches).

The array patterns described above are repeatedly employed in the plurality of chips in the X and Y directions.

A test of the internal circuits 1 in the chips A1, A2, B1 and B2 (probing test) is performed in the same manner as in the embodiment 1. After the completion of the probing test on the wafer, the probing pads 2 are cut off along the dicing lanes 4 in the Y direction and the dicing lanes 5 in the X direction in the dicing process so that the chip A1 is separated. In the separated chip A1, it becomes impossible to analyze the internal circuit 1 via the probing pads 2 which have already been removed. Further, the pitches of the needles used in the probing test can be alleviated in the same manner as in the embodiment 1.

In the present embodiment, the connecting parts 3 connected to the probing pads 2 are disposed on the four sides, which are the upper, lower, right and left sides, of the chips A1, A2, B1 and B2. As a result, the layout efficiency can be further preferable in comparison to the embodiment 1, and the tamper-resistance performance can be improved.

### Embodiment 3

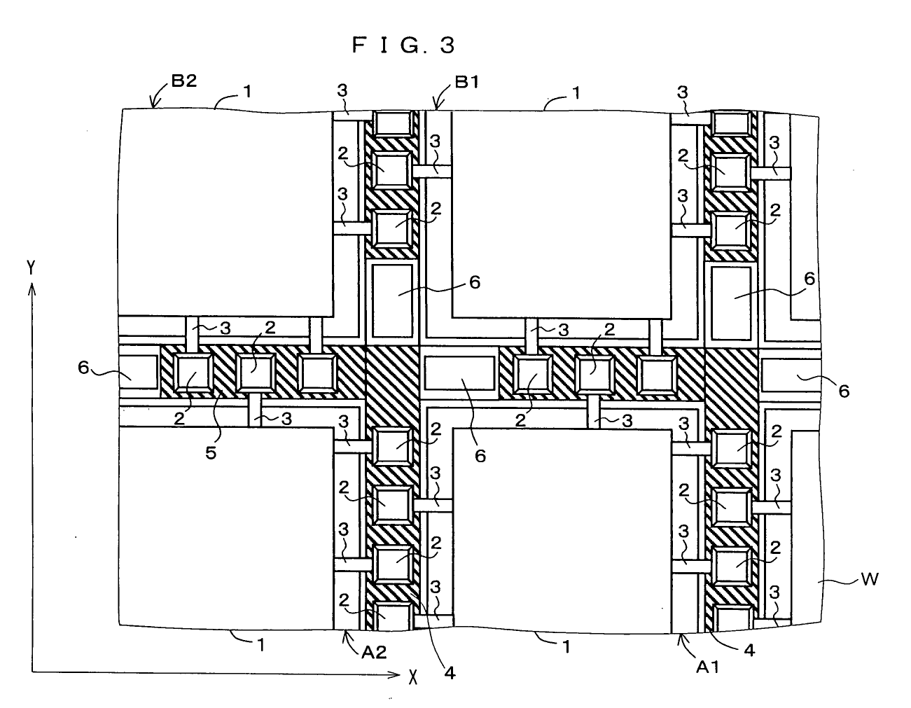

FIG. 3 shows a physical chip configuration in a semiconductor apparatus according to an embodiment 3 of the present invention. In FIG. 3, a reference numeral 6 denotes alignment marks with respect to reticle frames. The dicing lanes 4 along the Y direction and the dicing lanes 5 along the X direction are respectively provided with the alignment mark 6 for aligning the wafer W. The adjacent two chips share the probing pads 2 and the alignment marks 6 on the dicing lanes 4 and 5 disposed between the chips. Any other component, which is the same as described in the embodiment 2, is provided with the same reference symbol and not described here again.

According to the present embodiment, the following effect can be obtained in addition to the effect achieved by the embodiment 2. The present embodiment is characterized in that the dicing lanes 4 and 5 are shared by the adjacent two chips as the positions at which the probing pads 2 are provided, and the dicing lanes 4 and 5 are also thereby shared as the positions at which the alignment marks 6 are provided. Thereby, a degree of freedom in the layout of the dicing lane in a reticle design can be enhanced.

### Embodiment 4

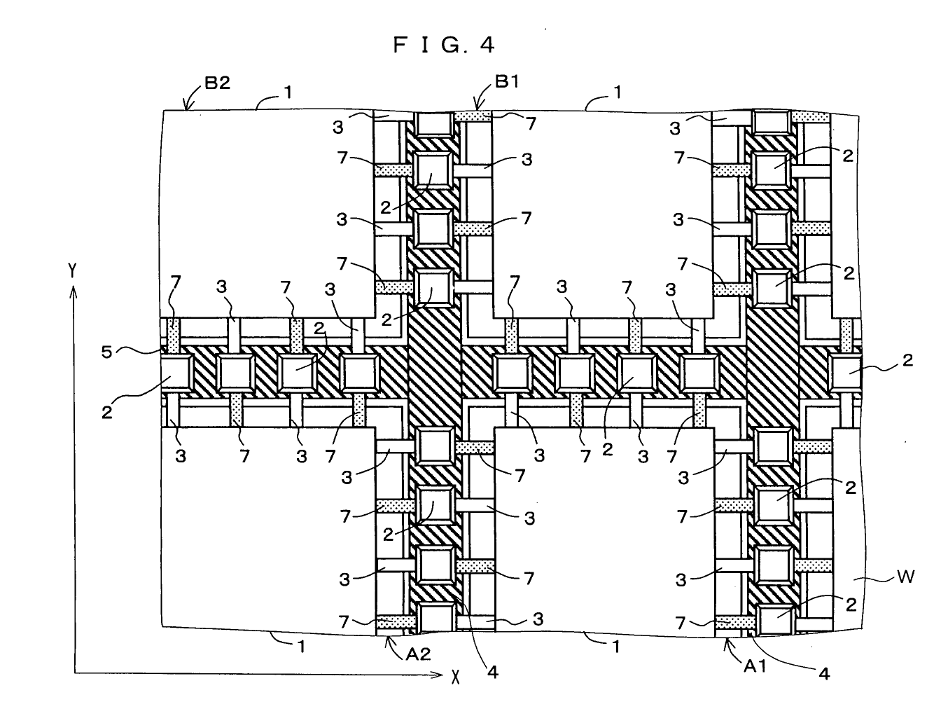

FIG. 4 shows a physical chip configuration in a semiconductor apparatus according to an embodiment 4 of the present invention. The present embodiment offers a basic constitution which is similar to that of the embodiment 2 described earlier referring to FIG. 2. Therefore, any component similar to or the same as the components shown in FIG. 2 is provided with the same reference symbol and not described here again. The present embodiment is characterized in that non-conductive dummy connecting parts 7 incapable of the electrical connection are provided.

The probing pads 2 provided in the dicing lanes 4 are respectively arranged in a row between the chips A1 and A2 and the chips B1 and B2 respectively adjacent to each other along the X direction in the drawing. The probing pads 2 are connected to the chips (A1 or A2) and (B1 or B2) via the connecting parts 3 on one side along the X direction in the drawing. At the time, the chips (A1 or A2) and (B1 or B2) connected to the probing pads 2 are alternately replaced along the dicing lanes 4 (along the Y direction).

The foregoing constitution is not any different to that of the embodiment 2, however, in the present embodiment, the chips (A1 or A2) and (B1 or B2) not connected to the probing pads 2 by the connecting parts 3 are combined with the probing pads 2 by the dummy connecting parts 7. The dummy connecting parts 7 are incapable of the electrical connection.

In the same manner, the probing pads 2 provided in the dicing lanes 5 are respectively arranged in a row between the chips A1 and B1 and the chips A2 and B2 respectively adjacent to each other along the Y direction in the drawing. The probing pads 2 are connected to the chips (A1 or A2) and (B1 or B2) via the connecting parts 3 on one side along the Y direction in the drawing. At the time, the chips (A1 or B1) and (A2 or B2) connected to the probing pads 2 are alternately replaced along the dicing lanes 5 (along the X direction).

The foregoing constitution is not any different to that of the embodiment 2, however, in the present embodiment, the chips (A1 or B1) and (A2 or B2) not connected to the probing pads 2 by the connecting parts 3 are combined with the probing pads 2 by the dummy connecting parts 7. The dummy connecting parts 7 are incapable of the electrical connection.

The probing pads 2 disposed on the dicing lanes 4 and 5 are connected to one of the chips adjacent to each other with the probing pads 2 interposed therebetween via the connecting parts 3, and connected to the other chip via the dummy connecting parts 7 (not actually connected but appear to be connected in a simulated manner). Thereby, on the dicing lanes 4 and 5, the probing pads 2 provided with the connecting parts 3 on one side thereof and the dummy connecting parts 7 on the other side thereof and the probing pads 2 provided with the dummy connecting pads 7 on one side thereof and the connecting parts 3 on the other side thereof are alternately disposed per pad.

The constitution shown in FIG. 4 is further provided with the dummy connecting parts 7 in addition to the constitution shown in FIG. 2. However, the dummy connecting parts 7 according to the present embodiment may be additionally provided in the constitution according to the embodiment 1 (FIG. 1) or the constitution according to the embodiment 3 (FIG. 3).

According to the present embodiment, the chips A1, A2, B1 and B2 separated as a result of cutting off the probing pads 2 after the probing test include a trace of the cut-off operation of the dummy connecting parts 7 not connected to the chips A1, A2, B1 and B2 apart from a trace of the cut-off operation of the probing pads 2 on the dicing sectional surfaces thereof. Further, the trace of the cut-off operation is present as if it is drawn into the respective chips. Therefore, the tamper-resistance performance against the illegal analysis can be further improved.

### Embodiment 5

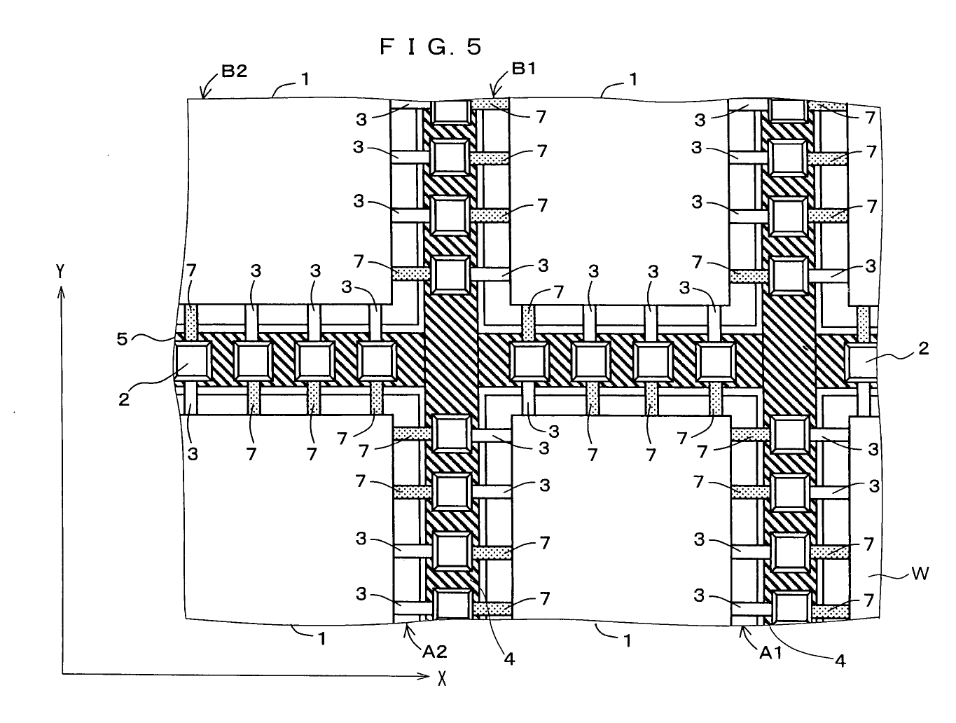

FIG. 5 shows a physical chip configuration in a semiconductor apparatus according to an embodiment 5 of the present invention.

In the embodiment 4, on the dicing lanes 4 in the Y direction, the probing pads 2 provided with the connecting parts 3 on the right side thereof and the dummy connecting parts on the left side thereof and the probing pads 2 provided with the dummy connecting parts 7 on the right side thereof and the connecting parts 3 on the left side thereof are alternately disposed per pad. Further, on the dicing lanes 5 in the X direction, the probing pads 2 provided with the connecting parts 3 on the lower side thereof and the dummy connecting parts on the upper side thereof and the probing pads 2 provided with the dummy connecting parts 7 on the lower side thereof and the connecting parts 3 on the upper side thereof are alternately disposed per pad.

In contrast, though the connecting parts 3 and the dummy connecting parts 7 are provided in the embodiment 5 in the same manner, the arrangement order of the connecting parts 3 and the dummy connecting parts 7 is not based on the regularity that they are alternately disposed per pad. The connecting parts 3 and the dummy connecting parts 7 are irregularly disposed. In FIG. 5, on the dicing lanes 4, the arrangement order of the connecting parts 3 and the dummy connecting parts 7 is alternate per two pads, per two pads, per pad, per three pads from left upward in the drawing. Further, on the dicing lanes 5, the arrangement order of the connecting parts 3 and the dummy connecting parts 7 is alternate per pad, per three pads, per pad, per three pads from left to right in the drawing. The rest of the constitution is the same as described in the embodiment 4 shown in FIG. 4. Any like component, therefore, is provided with the same reference symbol and not described here again.

According to the present embodiment, there is not any regularity in the arrangement order of the connecting parts 3 connected to the chips A1, B1, A2 and B2 and the dummy connecting parts 7 not connected to the chips A1, B1, A2 and B2, which increases the difficulty of the analysis in comparison to the embodiment 4.

### Embodiment 6

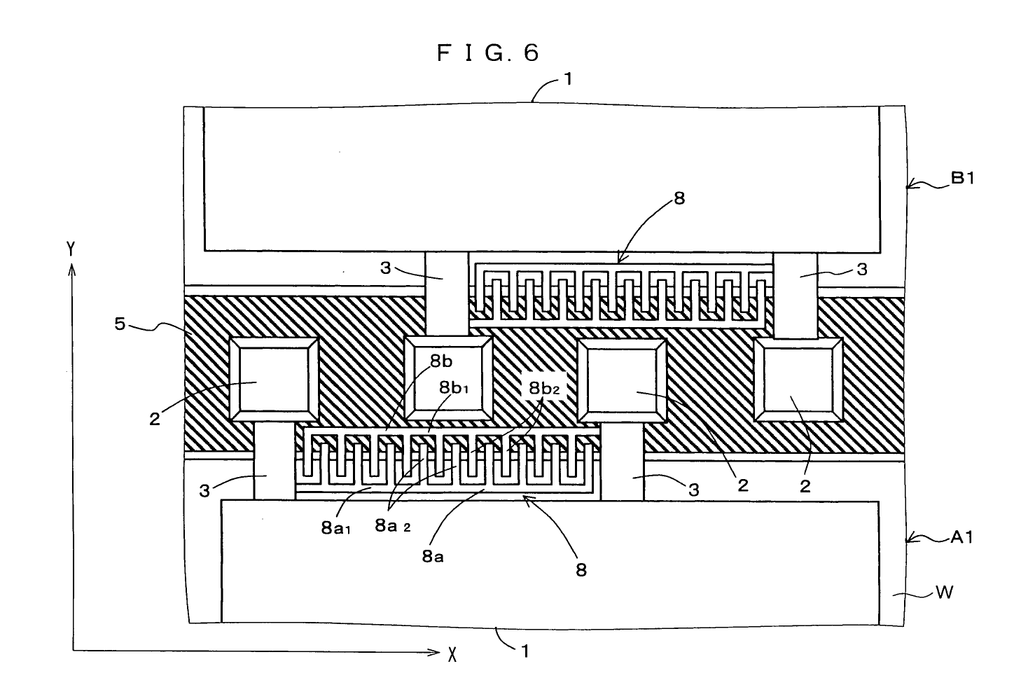

FIG. 6 shows a physical chip configuration in a semiconductor apparatus according to an embodiment 6 of the present invention. The semiconductor chips (hereinafter, simply referred to as chips) A1 and B1 are disposed in the Y direction on the wafer W. The semiconductor apparatus according to the present embodiment comprises short-circuit connecting parts 8. The short-circuit connecting part 8 short-circuits the connecting parts 3 connected to the same chip A1 or B1 and adjacent to each other by means of a damage generated in the cut-off operation in the dicing process along the dicing edge (edge of the dicing lane 5).

The short-circuit connecting part 8 is formed from the combination of comb-like conductors 8a and 8b. The comb-like conductor 8a comprises a base portion 8a₁ connected to one of the connecting parts 3 adjacent thereto and extending toward the other connecting part 3. The comb-like conductor 8b comprises a base portion 8b₁ connected to one of the connecting parts 3 adjacent thereto and extending toward the other connecting part 3.

The base portions 8a₁ and 8b₁ extend along the X direction in the drawing (direction where the dicing edge extends) and disposed in parallel with each other. The base portions 8a₁ are disposed on the chips A1 and B1, while the base portions 8b₁ are disposed on the dicing lane 5. The base portions 8a₁ and 8b₁ face each other with the dicing edge interposed therebetween. The base portions 8a₁ and 8b₁ respectively comprise a plurality of comb-teeth parts 8a₂ and 8b₂ branched from the respective base portions. Top ends of the comb-teeth parts 8a₂ (8b₂) extend toward the other comb-teeth parts 8b₂ (8a₂). The top ends of the comb-teeth parts 8a₂ and 8b₂ are drawn into each other in such manner that they are meshed with each other with the dicing edge interposed therebetween, however, disposed so as to prevent the connection between them.

At the time of the test, the comb-like conductors 8a and 8b remain electrically separated from each other in the short-circuit connecting part 8. Therefore, the adjacent connecting parts 3 are also in the electrically-separated state.

When the probing pads 2 are cut off along the dicing lane in the dicing process, the damage generated then entangles the comb-teeth parts 8a₂ and 8b₂, and the generated entanglement consequently electrically short-circuits the adjacent connecting parts 3.

The chip A1 separated in the dicing process is installed in the IC card or the like. When the third person tries to peal the desired chip off the IC card or the like and analyze it in his/her pursuit of the illegal success with respect to the internal circuit 1 of the chip, the probing pads 2 have already been cut off and removed. Further, it is necessary to cancel the short-circuit state in the connecting parts 3 due to the entanglement of the comb-teeth parts 8a₂ and 8b₂ to thereby separate the connecting parts 3 in order to start the analysis via the dicing sectional surface. As a result, in the present embodiment, the difficulty of the illegal analysis is further increased and the tamper-resistance performance is remarkably improved in comparison to the respective embodiments described earlier.

While there has been described what is at present considered to be preferred embodiments of this invention, it will be understood that various modifications may be made therein, and it is intended to cover in the appended claims all such modifications as fall within the true spirit and scope of this invention.

What is claimed is:

1. A semiconductor apparatus comprising:
a semiconductor wafer;
a plurality of semiconductor chips provided on the semiconductor wafer;
a dicing lane provided between the adjacent two semiconductor chips and representing a region to be cut off when the semiconductor wafer is cut for each of the semiconductor chips;
a plurality of probing pads disposed in a row on the dicing lane, and
connecting parts for connecting the respective probing pads to one of the semiconductor chips facing each other with the probing pads interposed therebetween, wherein
the semiconductor chips are connected to at least one of the plurality of probing pads via the connecting parts.

2. A semiconductor apparatus as claimed in claim 1, wherein
the semiconductor chips connected to the probing pads by the connecting parts are replaced on a regular basis along the dicing lane.

3. A semiconductor apparatus as claimed in claim 1, wherein
the semiconductor chips connected to the probing pads by the connecting parts are replaced on an irregular basis along the dicing lane.

4. A semiconductor apparatus as claimed in claim 1, wherein
the probing pads are disposed in a row based at identical pitches in a pair of dicing lanes facing each other with one of the semiconductor chips interposed therebetween, and
one of the two probing pads at identical positions in the respective rows of the pair of dicing lanes is connected to the one of the semiconductor chips by the connecting parts.

5. A semiconductor apparatus as claimed in claim 4, wherein
the probing pads are disposed in a row at identical pitches in another pair of dicing lanes facing each other with one of the semiconductor chips interposed therebetween, and
one of the two probing pads at identical positions in the respective rows of the another pair of dicing lanes is connected to the one of the semiconductor chips by the connecting parts.

6. A semiconductor apparatus as claimed in claim 1, wherein
a step alignment mark is provided in the dicing lane.

7. A semiconductor apparatus as claimed in claim 1, wherein
dummy connecting parts for connecting the respective probing pads to the other semiconductor chip unconnected via the connecting parts are further provided.

8. A semiconductor apparatus as claimed in claim 1, wherein
a short-circuit connecting part for short-circuiting the connecting parts by means of a damage generated in a dicing process is provided between the connecting parts connected to same the semiconductor chip and adjacent to each other.

9. A semiconductor apparatus as claimed in claim 1, wherein
the short-circuit connecting part comprises a pair of comb-like conductors disposed along an edge of the dicing lane,
one of the comb-like conductors is connected to one of the connecting parts adjacent thereto,
the other of the comb-like conductors is connected to the other of the connecting parts adjacent thereto, and
top-ends of the both comb-like conductors are drawn into each other in a comb-teeth manner in an non-connected state.
